(19) United States
(12) Patent Application Publication
(10) Pub. No.: US 2017/0085212 A1
(43) Pub. Date: Mar. 23, 2017

(54) High Temperature Spectrally Selective Thermal Emitter

(71) Applicants: Sandia Corporation, Albuquerque, NM (US); Physical Sciences Inc., Andover, MA (US)

(72) Inventors: Eric A. Shaner, Rio Rancho, NM (US); Jeffrey C. Cederberg, Albuquerque, NM (US); David N. Woolf, Somerville, MA (US); Joel M. Hensley, Chelmsford, MA (US)

(21) Appl. No.: 14/706,271

(22) Filed: May 7, 2015

Related U.S. Application Data
(60) Provisional application No. 61/991,747, filed on May 12, 2014.

(51) Int. Cl. H02S 10/30; H01L 31/0304; H01L 31/0693

(52) U.S. Cl. CPC H02S 10/30; H01L 31/0693; H01L 31/03046

(57) ABSTRACT

The present invention enables elective emission from a heterogeneous metasurface that can survive repeated temperature cycling at high temperatures (e.g., greater than 1300 K). Simulations, fabrication and characterization were performed for an exemplary cross-over-a-backplane metasurface consisting of platinum and alumina layers on a sapphire substrate. The structure was stabilized for high temperature operation by an encapsulating alumina layer. The geometry was optimized for integration into a thermophotovoltaic (TPV) system and was designed to have its emissivity matched to the external quantum efficiency spectrum of 0.6 eV InGaAs TPV material. Spectral measurements of the metasurface resulted in a predicted 32% optical-to-electrical power conversion efficiency. The broadly adaptable selective emitter design can be easily scaled for integration with TPV systems.

### CROSS-REFERENCE TO RELATED APPLICATION

This application claims the benefit of U.S. Provisional Application No. 61/991,747, filed May 12, 2014, which is incorporated herein by reference.

### STATEMENT OF GOVERNMENT INTEREST

This invention was made with Government support under contract no. DE-AC04-94AL85000 awarded by the U.S. Department of Energy to Sandia Corporation. The Government has certain rights in the invention.

### FIELD OF THE INVENTION

The present invention relates to thermophotovoltaic energy conversion and, in particular, to a high temperature spectrally selective thermal emitter that can improve the thermodynamic efficiency of thermophotovoltaic energy conversion systems.

### BACKGROUND OF THE INVENTION

Thermophotovoltaic (TPV) energy conversion was first identified as a promising technology for converting waste heat into electricity in the 1960s. Since then, the potential of combustion-TPV systems to act as compact, portable power sources with energy densities nearly 10 times that of rechargeable batteries that are critical for a broad range of military and commercial applications has been demonstrated. See L. M. Fraas et al., Semiconductor Science and Technology 18, S247 (2003); and W. R. Chan et al., Proceedings of the National Academy of Sciences 110, 5309 (2013). TPV systems convert thermal radiation emitted from a high temperature source (the emitter) into electricity by means of a photovoltaic (PV) diode. If a TPV system is treated as a heat engine with hot (T_{BB}) and cold sides (T_{PV}), the theoretical thermodynamic (Carnot) efficiency limit can be calculated as η_{Carnot}=[T_{BB}−T_{PV}]/T_{BB}. For T_{BB}=1300 K, T_{PV}=300 K, η_{Carnot}=0.77. In practice, the efficiencies of TPV systems have been fundamentally limited to ˜15% by the mismatch between the blackbody spectrum of the heated emitter and the external quantum efficiency (EQE) of the PV material. Other system considerations have reduced demonstrated efficiencies of full combustion-TPV systems to ·2.5%. Thus, a significant amount of work over the past 30 years has focused on improving the optical-to-electrical conversion efficiency by recycling out-of-band photons, using multiple bandgap cells, modifying the emissivity of an object away from the typical blackbody, or a combination of these techniques. See T. J. Coutts and James S. Ward, IEEE Transactions on Electron Devices 46, 2145 (1999); L. D. Woolf, Solar Cells 19, 19 (1986); R. A. Lowe et al., Applied Physics Letters 64, 3551 (1994); I. Celanovic et al., Applied Physics Letters 92, 193101 (2008); Y. Avitzour et al., Physical Review B 79, 045131 (2009); and Y. Xiang Yeng et al., Optics Express 21, A1035 (2013).

A selective emitter emits thermal radiation in a much narrower spectral range than a blackbody at the same temperature. Numerous geometries for modifying the emission spectrum have been studied, including metal (such as tungsten) photonic crystals, inverse opals, and metal-dielectric-metal (MDM) metasurfaces. See I. Celanovic et al., Applied Physics Letters 92, 193101 (2008); Y. Avitzour et al., Physical Review B 79, 045131 (2009); H. Sai et al., Applied Physics Letters 82, 1685 (2003); K. A. Arpin et al., Nature Communications 4 (2013); X. Liu et al., Physical Review Letters 107, 045901 (2011); and C. Wu et al., Journal of Optics 14, 024005 (2012). While the first two groups have shown promise regarding emissivity and survivability at operating temperatures, questions remain about the ability to scale these geometries beyond laboratory demonstrations. MDM metasurfaces, on the other hand, can easily be fabricated by standard foundry lithography techniques while exhibiting extremely tailorable emission spectra that can be made angle-independent when the layer thicknesses are significantly sub-wavelength. See Y. Avitzour et al., Physical Review B 79, 045131 (2009). However, the MDM metasurface geometry has been limited by delamination of the multilayer stack at high temperature due to differences in the coefficient of thermal expansion (CTE) generating interfacial stresses.

### SUMMARY OF THE INVENTION

The present invention is directed to a spectrally selective thermal emitter, comprising an optically thick metallic backplane, a sub-wavelength dielectric layer deposited on the metallic backplane, and an array of metallic resonator elements having subwavelength periodicity deposited on the dielectric layer, wherein the metallic backplane, dielectric layer, and array of metallic resonator elements have similar coefficients of thermal expansion up to a high temperature and wherein the thermal emitter provides enhanced absorption of incident light at a resonance wavelength. The high temperature can be greater than 900 K, and preferably greater than 1300 K. For example, for an operating temperature above 1300 K, the metallic backplane and the array of metallic resonator elements can comprise platinum and the dielectric layer can comprise alumina. The resonator elements be any shape that is symmetric in the x and y directions, such as a cross, circle, ellipse, square, or rectangle. For a resonance wavelength in the infrared (e.g., 1.5 μm), the periodicity of the array of metallic resonator elements can typically be less than 600 nm, the thickness of the dielectric layer can be less than 100 nm, and the thickness of the metallic backplane can be greater than 100 nm. The metallic backplane can be deposited on a substrate, such as sapphire or alumina, having a similar CTE. The thermal emitter can further comprise a transparent encapsulant, such as alumina, deposited on the array of metallic resonator elements.

A TPV system can further comprise a thermophotovoltaic material to absorb the spectrally selective emission of the thermal emitter when heated to the high temperature and convert the absorbed emission into electricity by means of a photovoltaic diode. Preferably the spectrally selective emission is well matched with the most efficient conversion characteristics of the photovoltaic diode. For example, the thermophotovoltaic material can comprise InGaAs or InGaAsSb.

As an example, a spectrally-selective emitter based on a cross-over-a-backplane metasurface design was demonstrated which can survive temperature cycling at 1300 K and can demonstrate η_{TPV}>0.32, η_{spec}>0.40, and Pₒᵤₜ>1.8 W/cm² when coupled to a 0.6 eV InGaAs TPV cell at 1300 K. An Al₂O₃ encapsulation layer stabilized the cross-on-a-backplane geometry when raised to 1300 K. Because of its geometry and heterogeneous structure the invention can easily be scaled using nanoimprint or stepper lithography in order to cover large surfaces in a cost-effective manner, making it a viable candidate for future commercial TPV systems.

### BRIEF DESCRIPTION OF THE DRAWINGS

The detailed description will refer to the following drawings, wherein like elements are referred to by like numbers.

FIG. 1(a) shows an exemplary MDM metasurface design comprising an array of platinum crosses above a platinum backplane with an amorphous Al₂O₃ spacer layer. FIG. 1(b) shows a fabrication procedure.

FIG. 2(a) is a graph of decomposition temperatures of potential dielectric materials. FIG. 2(b) is a graph of melting points of potential metals.

FIG. 3(a) shows simulated reflection spectra and FTIR reflectance spectra for the unencapsulated structure. FIG. 3(b) shows reflectance for five different encapsulated structures with w=275 nm. SEM images of the unencapsulated and encapsulated structures are shown in the insets. The SEM image of the encapsulated structure appears blurry because the imaging electrons do not penetrate the encapsulating layer.

FIG. 4(a) shows reflectivity of the encapsulated emitter before, after a two minute thermal anneal at 1300 K and after three anneals and 12 total minutes at 1300 K. FIG. 4(b) shows a pre-anneal optical image of ten of the 500 um×500 um arrays. FIG. 4(c) shows an SEM image of one part of one of the arrays. FIGS. 4(d) and 4(e) show post anneal optical and SEM images revealing no microscopic or macroscopic morphological change in the metasurface. FIGS. 4(f)-(j) show the same as FIGS. 4(a)-(e) but for the unencapsulated structure. All curves in FIGS. 4(a) and 4(f) correspond to the emitter array in the second row and fourth column of the optical images, with w=275 nm, l=250 nm, p=550 nm.

FIG. 5 shows a model of selective emitter-TPV system at 1300 K. The black body power and normalized photon density spectra are plotted on the right vertical axis and used to calculate the radiated power and radiated photon density of the selective emitter, respectively (also plotted on the right vertical axis). The emissivity, c, of the metasurface and the EQE of the PV material are plotted along the left vertical axis. The light and dark shaded volumes represent the radiated power at the emitter (P_{rad}) and the power absorbed by the PV material (Pₒᵤₜ), respectively.

### DETAILED DESCRIPTION OF THE INVENTION

A metasurface comprises an array of two-dimensional (2D) metallic resonator elements with subwavelength periodicity. Despite having negligible thicknesses as compared to the incident wavelength, metasurfaces are characterized by the ability to strongly manipulate both the amplitude and phase of incident light near (plasmonic) resonances of the unit cell constituents. By itself, a metasurface can only control the phase in a limited range, from 0 to π (radians), due to the Lorentz-like polarizabilities of the resonant elements. Therefore, for full control of the phase space, an MDM metasurface places the array of metal nanostructures in dose proximity to a metal backplane, only separated by an optically thin dielectric spacer layer. The MDM metasurface couples to both the electric and magnetic components of incident electromagnetic radiation and enables the reflectance to be minimized at a certain frequency by impedance matching to free space.

According to the present invention, the problem of thermal delamination of an MDM metasurface can be mitigated by properly choosing the metals and dielectrics to be non-reacting and have similar CTE up to high temperature (>1300 K), thereby providing a robust, scalable metamaterial selective emitter. As an example of the invention, below is described the modeling, fabrication, and characterization of an MDM metasurface with a dielectrically symmetric geometry comprised of a platinum cross above a platinum backplane, an alumina spacer layer and alumina encapsulation on a sapphire substrate that can survive repeated temperature cycling to 1300 K. With this geometry, the model predicts at least 32% energy conversion efficiency, 40% spectral efficiency, and 1.8 W/cm² of output power when coupled with a 0.6 eV strain-relaxed InGaAs PV material. See S. L. Murray et al., Semicond. Sci. Technology 18, S202 (2003); and J. G. Cederberg et al., J. Crystal Growth 310, 3453 (2008).

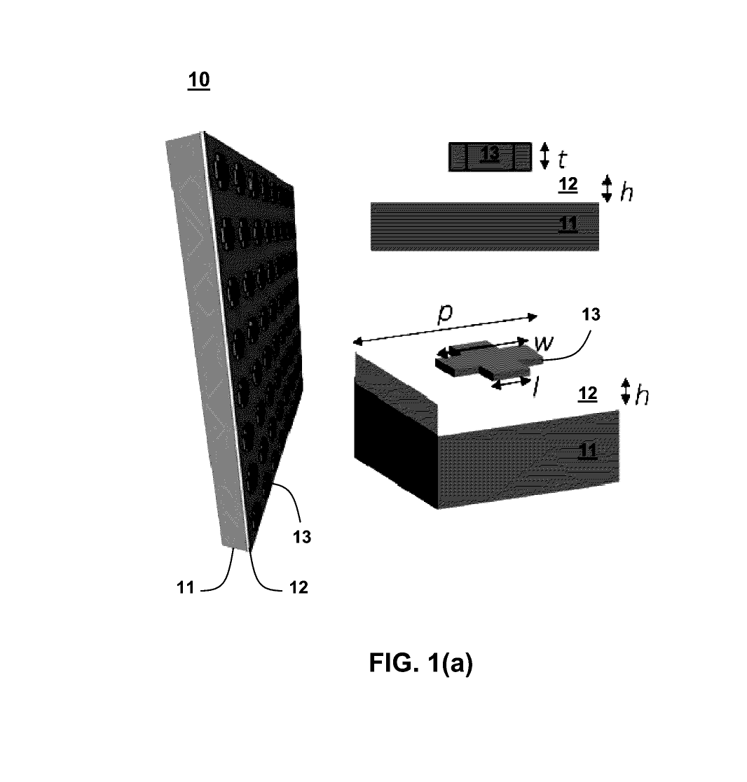

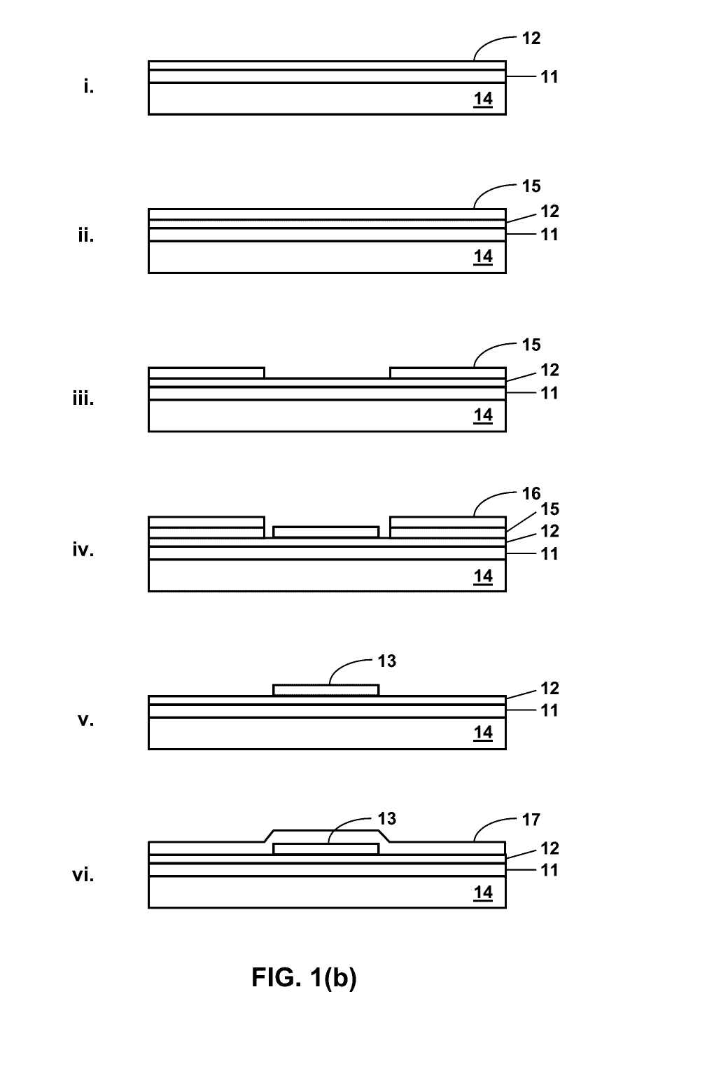

An exemplary emitter design is shown in FIG. 1(a). The exemplary MDM metasurface 10 comprises an array of platinum crosses 13 above a platinum backplane 11 with an amorphous Al₂O₃ spacer layer 12 therebetween. The metallic backplane 11 is preferably thick enough to prevent light transmission, thereby providing a narrow band absorber with high absorptivity. Different resonant elements 13 with different geometries and sizes can be used, depending on the absorption band(s) desired. A final 150 nm thick Al₂O₃ encapsulation layer on top of the Pt crosses is not shown in the figure for clarity. Side view and perspective view illustrations of a unit cell of the metasurface are shown at right in FIG. 1(a). The design has five degrees of freedom: p (unit cell period), h (thickness of the spacer layer), t (thickness of the cross), w (long dimension of the cross), and l (short dimension of the cross). The five device parameters—t, h, p, w, and l—are labeled on the unit cell. A material system was chosen to maintain performance at high temperature and in an air environment. Platinum was used as a metal because it has good optical properties and should not oxidize at these temperatures in air. Additionally, it has well matched CTE to Al₂O₃ from room temperature to 1500 K, decreasing the likelihood of delamination. See L. B. Freund and S. Suresh, Thin Film Materials, Cambridge University Press, Cambridge, UK (2006). The design of the present invention uses a different set of materials and operates in a different design parameter regime than prior demonstrations. See X. Liu et al., Physical Review Letters 107, 045901 (2011); and Q. Feng et al., Optics Letters 37, 2133 (2012). The mechanism for the resonance has been previously described. See H.-T. Chen, Optics Express 20, 7165 (2012).

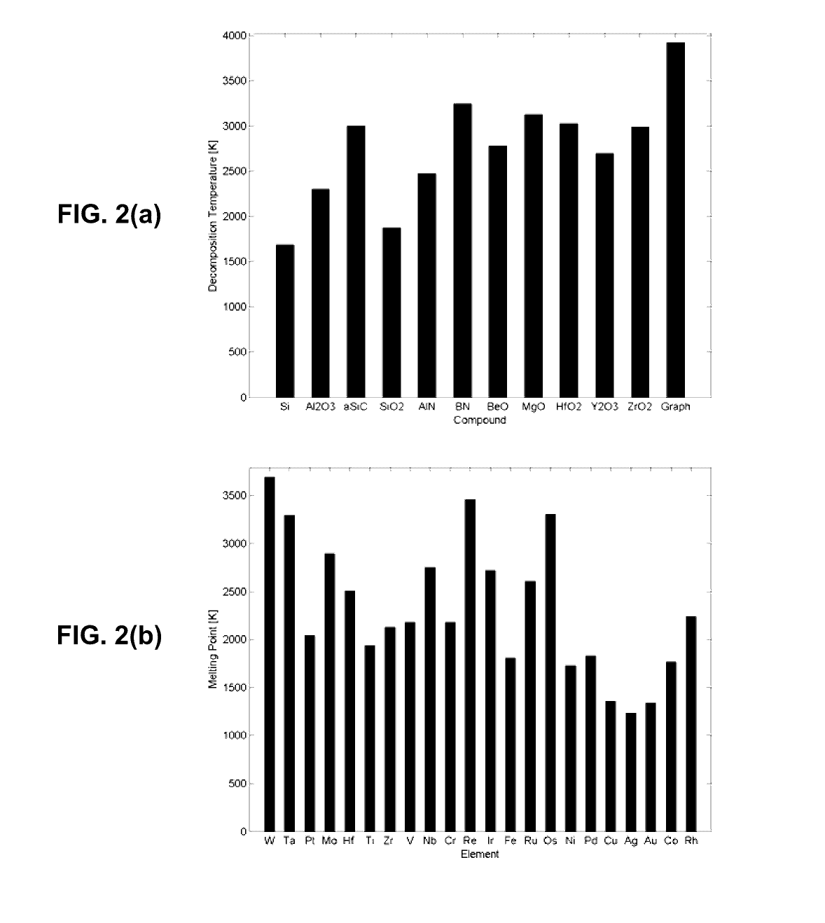

Other MDM materials can also be used. FIG. 2(a) shows a range of potential dielectric materials that can be used as a dielectric and/or as an encapsulant, including Si, Al₂O₃, SiC, SiO₂, AlN, BN, BeO, MgO, HfO₂, Y₂O₃, ZrO₂, or graphite. The melting point of the dielectric material is preferably approximately 50% larger than the operating temperature of the MDM emitter to retain structural integrity. The encapsulant should be chemically similar to avoid reactions that can be accelerated at high temperatures. The selection of potential metals is wider still, including W, Ta, Pt, Mo, Hf, Ti, Zr, V, Nb, Cr, Re, Ir, Fe, Ru, Os, Ni, Pd, Cu, Ag, Au, Co, Rh, or alloys thereof, as shown in FIG. 2(b). Metals have similar structural limitations as dielectrics. In addition, thin patterned metal films are prone to delaminate from the dielectric and ball up, thereby lowering their surface energy at temperatures well below the melting point.

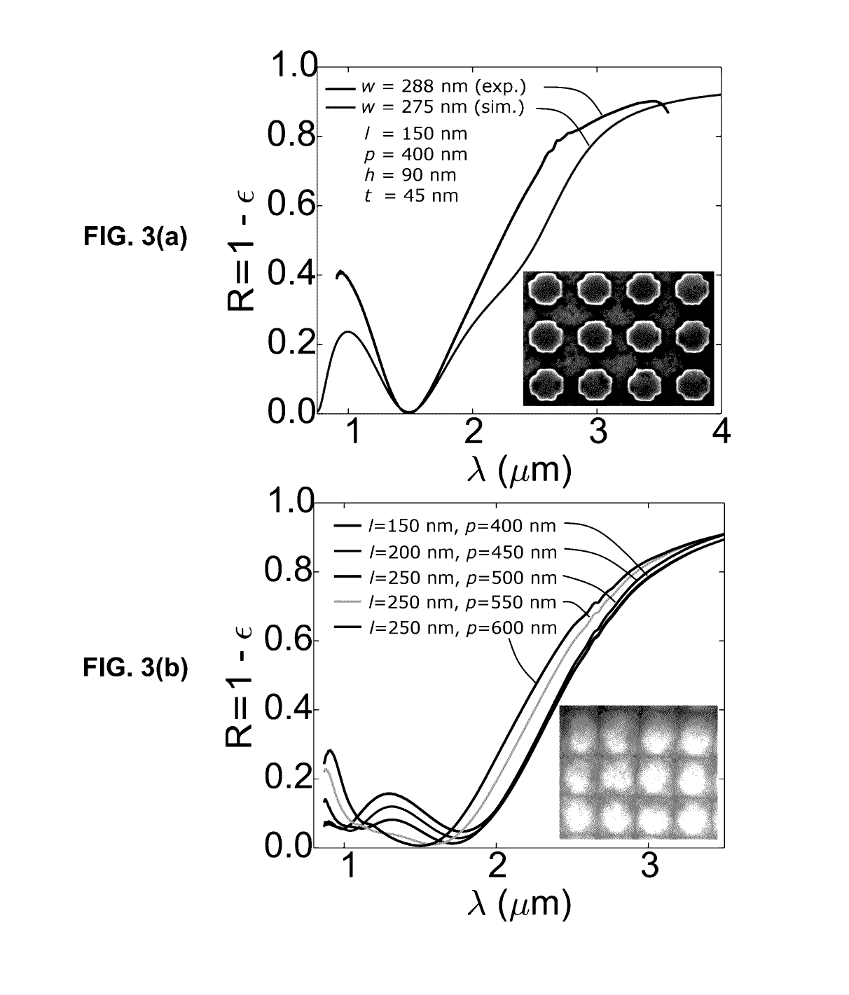

A fabrication procedure for the exemplary thermal emitter comprising a platinum-alumina-platinum metasurface is shown in FIG. 1(b). At step (i), an optically thick (200 nm) layer of Pt 11 (with a 20 nm chrome adhesion layer) and h=90 nm thick layer of Al₂O₃ 12 were e-beam evaporated onto a crystalline sapphire (Al₂O₃) wafer 14. Next, at step (ii), a layer of e-beam resist (EBR) 15 was spun onto the wafer, exposed by an e-beam writer, and then developed to remove the exposed portion of the EBR and thereby expose the Al₂O₃ underneath at step (iii). A second layer of Pt 16 (thickness t=45 nm) was then blanket deposited on the whole chip at step (iv), followed by lift-off of the remaining EBR to provide the Pt crosses 13 at step (v). An SEM image of the resonator array at this stage in the fabrication process can be seen in the inset of FIG. 3(a). Finally, an additional 150 nm-thick layer of Al₂O₃ 17 was deposited via Atomic Layer Deposition (ALD) at step (vi) to encapsulate the crosses (FIG. 3(b), inset). Twenty five 500 μm×500 μm arrays of crosses were fabricated, with 400 nm<p<600 nm, 150 nm<l<250 nm, 250 nm<w<300 nm in each emitter array (note that w=l corresponds to a square). These numbers were chosen based on reflectance simulations of the unencapsulated structure performed using an FDTD package. A search of parameter space led to a set of optimized parameters that resulted in a broad and deep reflection dip that is independent of the incident angle of radiation. A representative reflectivity spectrum can be seen in FIG. 3(a) for w=275 nm, l=150 nm, p=400 nm, h=90 nm, and t=45 nm.

The unencapsulated (FIG. 3(a)) and encapsulated (FIG. 3(b)) structures were measured in a microscope-coupled Fourier transform infrared (FTIR) spectrometer. By comparing the curves in FIG. 3(a), good agreement is seen between simulation and experiment. FTIR measurements of the encapsulated sample's infra-red absorption features (FIG. 3(b)) reveal a broadening of the resonances compared to the unencapsulated structure.

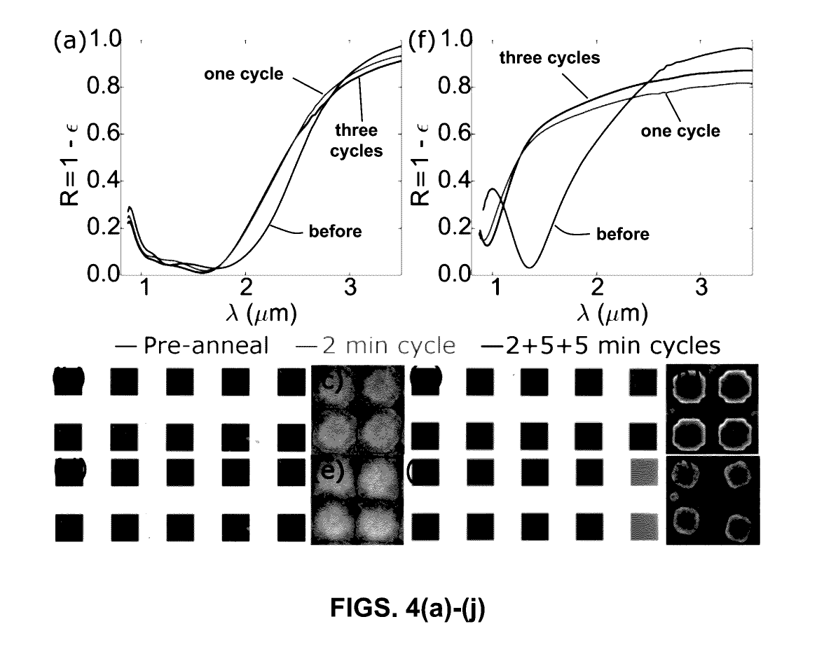

To test the multilayer MDM structure's robustness to high-temperature thermal cycling, the encapsulated samples were annealed in an argon atmosphere at 1300 K, in two, five, and five minute increments. After each annealing cycle, the emitter arrays were characterized with the FTIR spectrometer and an optical microscope. FIG. 4(a) shows the FTIR spectrum for a particular pattern (w=275 nm, l=250 nm, p=550 nm) before thermal cycling, after the first two-minute cycle and after three cycles and twelve total minutes at 1300 K. The slight shift from the pre-baked spectrum after the first bake is likely due to a measured 5 nm change in the thickness of the ALD-deposited Al₂O₃ that occurred because of densification during the initial anneal. FIGS. 4(b) and 4(c) show an optical image for 10 of the 25 pre-anneal encapsulated metamaterial arrays and a representative SEM image of four unit cells of one of the arrays, respectively. FIGS. 4(d) and 4(e) are the same as FIGS. 4(b) and 4(c) but after the three thermal cycles. By comparing the pre- and post-cycle images, no discernable macroscopic change was observed in the visible-frequency spectral properties or microscopic change in the shape of the encapsulated crosses after all three thermal cycles. Additionally, there is no evidence of delamination anywhere on the chip, as the post-anneal sample resembles the pre-anneal sample. Combined with the FTIR measurements, these results indicate that the encapsulated structure is highly stable to thermal cycling.

For comparison, the same data are plotted for the unencapsulated structure in FIGS. 4(f)-(j). Upon heating, the Pt crosses undergo a morphological change (FIG. 4(j) inset compared to FIG. 4(h)) to lower their energy by reducing their surface area, forming globules, which results in a dramatic shift in the infrared reflection spectra (FIG. 4(f)) as well as the optical appearance (FIGS. 4(g) to (j)). The morphological change occurs within the first two minutes at 1300 K and the new surface configuration is stable to additional heating and temperature cycling, as indicated by the similarity between the respective curves in FIG. 4(f).

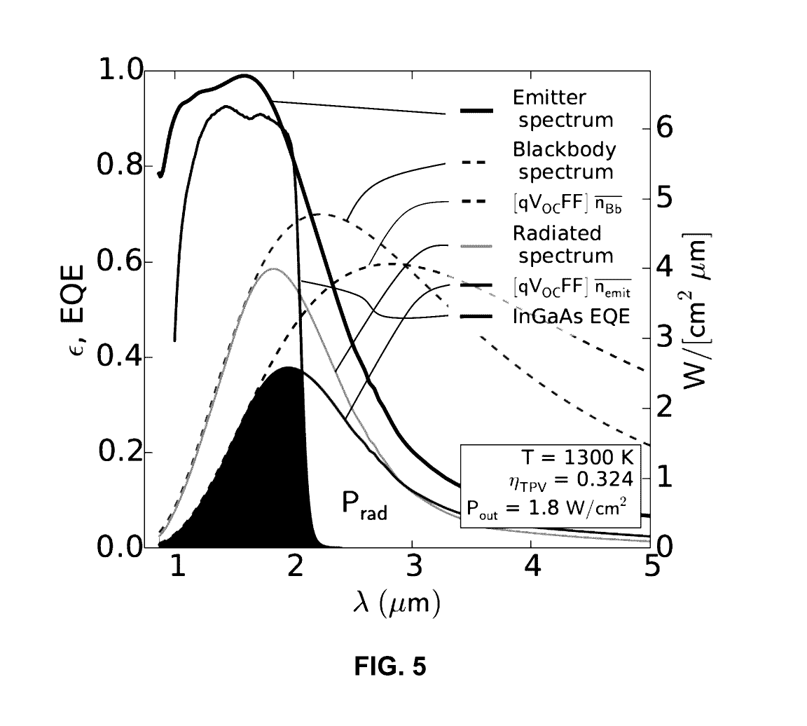

Using the measured absorption spectra to represent the emissivity (εₑₘᵢₜ(ω)=1−R(ω)) of the metasurface, the behavior of the emitter in a TPV system was modeled and the TPV cell efficiency η_{TPV} and the generated power Pₒᵤₜ were calculated, as shown in FIG. 5. η_{TPV} can be understood as the product of the power-spectral efficiency (ηₚₛ: power absorbed by the PV diode divided by the power emitted by the selective emitter, P_{rad}) and the diode's efficiency (η_{diode}: power conversion efficiency of absorbed photons). Consequently, the TPV cell efficiency is

$${η}_{TPV} = {η}_{ps} {η}_{diode} = \frac{{P}_{abs}}{{P}_{rad}} \frac{{P}_{out}}{{P}_{abs}} = \frac{{V}_{OC} {I}_{SC} FF}{{P}_{rad}} , \qquad ( 1 )$$

where V_{OC} is the diode's open circuit voltage, I_{SC} is the diode's short circuit current, and FF is the fill factor, which are defined below. Since the emitter is at Tₑₘᵢₜ=1300 K and the PV diode is at T_{PV}=300 K, the amount of power radiated to the TPV cell, P_{rad}, can be expressed as:

$${P}_{rad} = {\int }_{0}^{∞} \frac{{ω}^{2}}{{( 2 π )}^{2} {c}^{2}} \frac{ℏω}{exp ( \frac{ℏω}{{kT}_{emit}} ) - 1} ɛ ( ω ) d ω , \qquad ( 2 )$$

where c is the speed of light, k is the Boltzmann constant, is the reduced Planck constant, ω is the angular frequency, and the negligible radiation path from the PV cell to the emitter is ignored because Tₑₘᵢₜ>>T_{PV} and angle and polarization-independent emission is assumed. The integrand of Eq. 2 with ε=1, assuming a perfect blackbody, is drawn as the dashed line labeled “Blackbody spectrum” in FIG. 5 and plotted on the right vertical axis, while the emissivity εₑₘᵢₜ (solid line labeled “Emitter spectrum”) is plotted along the left vertical axis. The full integrand of Eq. 2 (the product of the blackbody power spectrum and εₑₘᵢₜ) represents the actual emitted power at 1300 K and is plotted as the solid line labeled “Radiated spectrum” along the right vertical axis.

The amount of power generated by the PV cell (Pₒᵤₜ) is proportional to the number of electron-hole pairs generated and thus is also proportional to the number of emitted, above-bandgap photons, nₑₘᵢₜ (as opposed to the emitted power density) which can be written as

$${n}_{emit} = {\int }_{{ω}_{g}}^{∞} \frac{{ω}^{2}}{{( 2 π )}^{2} {c}^{2}} \frac{1}{exp ( \frac{ℏω}{{kT}_{emit}} ) - 1} ɛ ( ω ) d ω . \qquad ( 3 )$$

The percentage of incident photons converted to electron-hole pairs is known as the external quantum efficiency (EQE) of the TPV material and is plotted as the solid line labeled “InGaAs EQE” against the left vertical axis of FIG. 5. The integrand of Eq. 3 with ε=1 represents the blackbody photon density (n̅_̅{̅B̅B̅}̅) at 1300 K and is plotted as the dashed line labeled “qV_{OC}FFn̅_̅{̅B̅b̅}̅”. The integrand with ε=εₑₘᵢₜ represents the emitted photon density of the metamaterial emitter, “n̅ₑ̅ₘ̅ᵢ̅ₜ̅”, and is plotted as the solid line labeled “qV_{OC}FFn̅ₑ̅ₘ̅ᵢ̅ₜ̅”. Both curves are normalized to place them in units of power by qV_{OC}FF so that they can be plotted along the right vertical axis. To obtain this normalization, the standard model of a PV diode was used to find I_{SC} and V_{OC} and then find the maximum extractable power by finding Vₘₐₓ and Iₘₐₓ, which allowed to calculate the fill factor FF=IₘₐₓVₘₐₓ/I_{SC}V_{OC}, which is 0.77 for this PV material. See P. Bhattacharya, Semiconductor Optoelectronic Devices, Prentice Hall, N.J. (1997). Using this normalization, the relevant figures of merit can be observed in FIG. 5 for the selective emitter. The light and dark shaded areas correspond to P_{rad} and Pₒᵤₜ, respectively, and thus η_{TPV} is visually approximated by the ratio of the dark area to the light area and the spectral efficiency (η_{spec})—the percentage of emitted photons converted to electron-hole pairs—is the ratio of the shaded dark area to the full area under the qV_{OC}FFn̅ₑ̅ₘ̅ᵢ̅ₜ̅ curve.

The post-thermal cycling emissivity of all twenty five arrays was characterized and the highest η_{TPV}Pₒᵤₜ was found to corresponded to w=275 nm, l=250 nm, p=550 nm when paired with the 0.6 eV GaAs TPV material, generating 1.8 W/cm² with η_{TPV}=0.32 and η_{spec}=0.40. The selective emitter of the present invention succeeds by significantly suppressing the emission of below-bandgap photons and having the peak of the emissivity align with the peak of the TPV EQE. The poor performance of a TPV system without a selective emitter can be seen in FIG. 5 by looking at the areas under the dashed curve labeled “Blackbody spectrum” and the dashed curve labeled “qV_{OC}FFn̅_̅{̅B̅B̅}̅”. The vast majority of emitted photons (>85%) are below-bandgap, corresponding to energy that will not be converted to electricity and could be absorbed elsewhere in the PV structure, which could raise the temperature of the TPV material and decrease its EQE. The selective emitter improves the efficiency of an overall combustion-TPV system by increasing η_{TPV}, thus decreasing wasted emission and also the amount of fuel needed to keep the emitter at 1300 K.

Additional gains can be achieved by using a TPV material with lower band gap than the 0.6 eV material used in this example. The metrics of the emitter-TPV cell system using four different TPV materials can be seen in Table 1. For each emitter at both temperatures, the measured emission spectra for each of the 25 arrays was input into the model to maximize η_{TPV}. Because the exemplary emitter was not designed to overlap with the EQEs of these materials, it is possible that the optimal efficiencies and output powers are higher than what is shown in this table. The system at 1500 K was also evaluated to illustrate the potential benefits of higher temperature operation. The quaternary, 0.52 eV InGaAsSb material outperforms the other three materials due to its low band gap and high EQE (>95%). Further system modifications, such as a dielectric coating that highly reflects below-band gap photons, can further improve the efficiencies. See Y. Xiang Yeng et al., Optics Express 21, A1035 (2013).

TABLE I
Comparison of TPV system metrics with different PV materials

| | Band | 1300 K | | | 1500 K | | |
|---|---|---|---|---|---|---|---|
| TPV | Gap | | | Pₒᵤₜ | | | Pₒᵤₜ |
| Material | (eV) | η_{TPV} | η_{spec} | (W/cm²) | η_{TPV} | η_{spec} | (W/cm²) |
| InGaAs | 0.60 | 0.33 | 0.41 | 1.8 | 0.37 | 0.47 | 4.8 |
| | 0.55 | 0.36 | 0.42 | 2.1 | 0.41 | 0.51 | 5.4 |
| | 0.50 | 0.34 | 0.29 | 2.1 | 0.39 | 0.38 | 5.2 |
| InGaAsSb | 0.52 | 0.41 | 0.60 | 2.5 | 0.45 | 0.66 | 6.0 |

See C. S. Murray et al., “Growth, Processing and Characterization of 0.55-eV n/p/n Monolithic Interconnected Modules,” Conference Record of the 28^{th} Photovoltaic Specialists Conference (2000), 1238; S. Wojtczuk, “Comparison of 0.55eV InGaAs single-junction vs. multi-junction TPV technology”, in Thermophotovoltaic Generation of Electricity: TPV3, AIP Conf. Proc. 401, 205 (1997); and M. W. Dashiell et al., IEEE Transactions on Electron Devices 53, 2879 (2006).

The present invention has been described as a high temperature spectrally selective thermal emitter. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A spectrally selective thermal emitter, comprising:
an optically thick metallic backplane,
a sub-wavelength dielectric layer deposited on the metallic backplane, and
an array of metallic resonator elements having subwavelength periodicity deposited on the dielectric layer,
wherein the metallic backplane, dielectric layer, and array of metallic resonator elements have similar coefficients of thermal expansion up to a high temperature and wherein the thermal emitter provides enhanced absorption of incident light at a resonance wavelength.

2. The thermal emitter of claim 1, wherein the high temperature is greater than 1300 K.

3. The thermal emitter of claim 1, wherein the metallic backplane comprises W, Ta, Pt, Mo, Hf, Ti, Zr, V, Nb, Cr, Re, Ir, Fe, Ru, Os, Ni, Pd, Cu, Ag, Au, Co, Rh, or alloys thereof.

4. The thermal emitter of claim 1, wherein the dielectric layer comprises Si, Al₂O₃, SiC, SiO₂, AlN, BN, BeO, MgO, HfO₂, Y₂O₃, ZrO₂, or graphite.

5. The thermal emitter of claim 1, wherein the metallic resonator elements comprise W, Ta, Pt, Mo, Hf, Ti, Zr, V, Nb, Cr, Re, Ir, Fe, Ru, Os, Ni, Pd, Cu, Ag, Au, Co, Rh, or alloys thereof.

6. The thermal emitter of claim 1, wherein the metallic backplane and the array of metallic resonator elements comprise platinum and the dielectric layer comprises alumina.

7. The thermal emitter of claim 1, wherein the resonator elements comprise a cross, circle, ellipse, square, or rectangle.

8. The thermal emitter of claim 1, wherein the resonance wavelength is in the infrared.

9. The thermal emitter of claim 1, wherein the periodicity of the array of metallic resonator elements is less than 1 micron.

10. The thermal emitter of claim 1, wherein the thickness of the dielectric layer is less than 100 nanometers.

11. The thermal emitter of claim 1, wherein the thickness of the metallic backplane is greater than 100 nanometers.

12. The thermal emitter of claim 1, further comprising a substrate and wherein the metallic backplane is deposited on the substrate.

13. The thermal emitter of claim 12, wherein the substrate comprises sapphire or alumina.

14. The thermal emitter of claim 1, further comprising an encapsulant deposited on the array of metallic resonator elements.

15. The thermal emitter of claim 14, wherein the encapsulant comprises alumina.

16. The thermal emitter of claim 1, further comprising a thermophotovoltaic material to absorb the spectrally selective emission of the thermal emitter when heated to the high temperature and convert the absorbed emission into electricity by means of a photovoltaic diode.

17. The thermal emitter of claim 16, wherein the thermophotovoltaic material comprises InGaAs or InGaAsSb.
